(19) United States
(12) Patent Application Publication
(10) Pub. No.: US 2018/0305219 A1
(43) Pub. Date: Oct. 25, 2018

(54) OXIDE SEMICONDUCTOR

(71) Applicant: National Institute of Advanced Industrial Science and Technology, Tokyo (JP)

(72) Inventors: Naoto Kikuchi, Ibaraki (JP); Kazuhiko Tonooka, Ibaraki (JP); Yoshihiro Aiura, Ibaraki (JP); Hirofumi Kawanaka, Ibaraki (JP); Ruiping Wang, Ibaraki (JP); Hiroshi Takashima, Ibaraki (JP); Akane Samizo, Ibaraki (JP); Shintarou Ikeda, Ibaraki (JP)

(21) Appl. No.: 15/769,612

(22) PCT Filed: Oct. 12, 2016
(86) PCT No.: PCT/JP2016/080205

§ 371 Date: Apr. 19, 2018

(30) Foreign Application Priority Data
Oct. 20, 2015 (JP) 2015-206351

(51) Int. Cl. C01G 33/00; H01L 29/24

(52) U.S. Cl. CPC C01G 33/006; H01L 29/24; C01P 2002/72; C01P 2002/36; C01P 2006/40

(57) ABSTRACT

There is provided an oxide semiconductor that is capable of achieving p-type semiconductor properties in the oxide semiconductor and has excellent transparency, mobility and weather resistance. The oxide semiconductor is achieved by an oxide composite having a pyrochlore structure that contains Sn and Nb whose composition ratio Sn/Nb is 0.81≤Sn/Nb<1.0. The oxide semiconductor has a wide bandgap of 2.2 eV, indicating that the oxide semiconductor has transparency in a visible spectrum and is a p-type semiconductor with high mobility. When Sn is less than a stoichiometric composition ratio in a composition formula of Sn₂Nb₂O₇, that is, when Sn/Nb<1, p-type semiconductor properties can be achieved by generation of a structural defect V″_{Sn}, and when the composition ratio Sn/Nb is greater than or equal to 0.81, the pyrochlore structure is obtained.

### CROSS-REFERENCE TO RELATED APPLICATIONS

This application is a National Stage application of International Patent Application No. PCT/JP2016/080205, filed on Oct. 12, 2016, which claims priority to Japanese Patent Application No. 2015-206351, filed on Oct. 20, 2015, each of which is hereby incorporated by reference in its entirety.

### TECHNICAL FIELD

The present invention relates to an oxide semiconductor including an oxide composite, and particularly relates to an oxide semiconductor capable of achieving p-type semiconductor properties.

### BACKGROUND

Conventionally, known examples of oxide composites include transparent conductive materials and transparent semiconductive materials having high transparency in a visible spectrum and showing high electrical conductivity, and these oxide composites are widely utilized for transparent electrodes and the like. Known examples of transparent semiconductors include In₂O₃, ZnO, SnO₂ and base materials of these compounds to which impurities are added, such as Sn-doped In₂O₃, Al-doped ZnO, Ga-doped ZnO, Sb-doped SnO₂ and F-doped SnO₂, all of which are n-type semiconductors having electrons that serve as charge carriers. On the other hand, some semiconductors are p-type semiconductors having electron holes that serve as charge carriers. When n-type and p-type semiconductors that are transparent in the visible spectrum are placed together, a p-n junction is formed, thereby making it possible to manufacture diodes, transistors, solar cells and the like that are transparent in the visible spectrum.

Cu₂O and NiO have been known as p-type semiconductors, but these compounds absorb light in the visible spectrum and are strongly colored, and thus, are not transparent. Research and development have been conducted for transparent p-type conductors since 1990, and several new transparent p-type conductors have been reported thereafter. Examples of the new transparent p-type conductors include: an oxide composite having a chemical formula of ABO₂ (where A=at least one of Cu or Ag, and B=at least one of Al, Ga, In, Sc, Y, Cr, Rh or La) having a delafossite structure; an oxychalcogenide compound represented by a chemical formula of LnCuOCh (where Ln=at least one of lanthanoid element or Y, and Ch=at least one of S, Se or Te); and zinc oxide represented by a chemical formula of ZnO. However, the compound having the delafossite structure has electron holes with low mobility. In addition, the oxychalcogenide compound has electron holes with considerably high mobility and high concentration but is undesirably oxidized under an atmosphere of air, which leads to substantial deterioration of properties. Furthermore, since zinc oxide is originally an n-type semiconductor having electrons that serve as charge carriers, it is necessary to reduce structural defect concentration that generate electrons as much as possible and to introduce structural defects that exhibit p-type semiconductor properties such as nitrogen. In this regard, since it is difficult to generate n-type structural defects and to reduce n-type structural defect concentration when introducing p-type structural defects, it is difficult to prepare and reproduce zinc oxide having p-type semiconductor properties. Therefore, it is difficult to achieve a transparent p-type semiconductor suitable for electronic devices.

There is a desire for an oxide semiconductor that is a semiconductor material resistant to oxidation reaction under an atmosphere containing oxygen. However, it is difficult to yield p-type conductivity in an oxide. This is because electrons at an upper edge of a valence band are localized on oxygen ions in an oxide. In order to reduce localization of electrons at an upper edge of a valence band in the delafossite compound, a d-orbital component of metal is introduced to the upper edge of the valence band, and in order to reduce localization of electrons at the upper edge of a valence band in the oxychalcogenide compound, a p-orbital component of a chalcogen element is introduced to the upper edge of the valence band. In addition, localization of electrons at the upper edge of each valence band can be further reduced by introducing an s-orbital component of metal having an electron orbital radius greater than that of the d-orbital or p-orbital component to the upper edge of the valence band, whereby high mobility can be obtained. Furthermore, it is possible for an isotropic spherical structure of the s-orbital component to suppress mobility from being reduced by a turbulent crystal structure that causes bond angle variation and bond distance variation. Based on this concept, it is reported that a p-channel transistor can be fabricated with using tin oxide (SnO) to which an s-orbital component of tin is introduced to an upper edge of its valence band (see, for example, International Publication No. 2010/010802). In addition, it is known that a bandgap of SnO is 0.7 eV, indicating a smaller energy than that in the visible spectrum, so that SnO is strongly colored in the visible spectrum, whereby transparency of SnO in the visible spectrum cannot be ensured.

In connection with oxides having a pyrochlore structure, the following documents are known.

It is reported that, in a metal oxide having a pyrochlore structure represented by a composition formula of Sn₂Nb₂O₇, an upper edge of a valence band includes Sn-5s components (see Y. Hosogi, Y. Shimodaira, H. Kato, H. Kobayashi, A. Kudo, Chemistry of Materials 20, 1299 (2008)).

Through a research regarding a structure of a compound represented by a simple composition formula of Sn₂Nb₂O₇, it is known that (1) a portion of a divalent Sn site is vacant, and (2) a portion of a tetravalent Sn obtained when a portion of a pentavalent Nb site was oxidized is substituted. These two structural defects can be represented by Sn₂₋ₓ(Nb_{2-y}Sn_{y})O_{7-x-0.5y}. Additionally, this research has described that a pyrochlore structure is maintained when a range of x, y=0.1 to 0.48 is satisfied (M. A. Subramanian, G. Aravamudan, G. V. Subba Rao, Progress in Solid State Chemistry 15, 55 (1983)).

In addition, it has been reported that irradiating light onto an oxide having a pyrochlore structure causes organic matters to decompose and causes the oxide to act as a photocatalyst (see Japanese Patent Application Laid-Open Publication No. 2003-117407 and Japanese Patent Application Laid-Open Publication No. 2004-344733). Japanese Patent Application Laid-Open Publication No. 2003-117407 discloses a photocatalyst of an oxide composite constituted by Sn₂Nb₂O₇ (oxide semiconductor) and titanium oxide. In Japanese Patent Application Laid-Open Publication No. 2003-117407, the photocatalyst includes an oxide composite having junctions for different kinds of oxide semiconductors in which electrons at a bottom of a conduction band and electrons at a top of a valence band have different energy levels. Japanese Patent Application Laid-Open Publication No. 2004-344733 discloses a photocatalyst having any one of a pyrochlore-related structure, an α-PbO₂ related structure, or a rutile-related structure represented by ABO₄₊ₓ (where −0.25≤x≤0.5, ion A is a Sn element, and ion B is one or more elements selected from Nb and Ta). This structure has regular oxygen ion vacancies that can be seen from a fluorite structure, and positions of the oxygen vacancies in a pyrochlore structure include regularly arranged cations that are filled with oxygen. In Japanese Patent Application Laid-Open Publication No. 2004-344733, a product described as Comparative Example 1 that has a pyrochlore structure of Sn₂Nb₂O₇ and is not oxidized has hardly any photocatalytic properties in contrast to the photocatalyst disclosed therein.

### SUMMARY

Conventionally, in an oxide semiconductor that is resistant to oxidation reaction under an atmosphere containing oxygen, it is difficult to achieve a transparent p-type semiconductor that is suitable for an electronic device. In particular, there is a desire to achieve a transparent semiconductor device by placing n-type and p-type semiconductors that are transparent in the visible spectrum together and forming the p-n junction. However, it has been difficult to achieve such a transparent semiconductor device.

The present invention is intended to solve these problems, and an object of the present invention is to provide a novel oxide semiconductor that absorbs less light in the visible spectrum and is capable of achieving high mobility of charge carriers. In addition, another object of the present invention is to provide an oxide semiconductor that exhibits p-type semiconductor properties.

In order to achieve the above-described object, the present invention has the following characteristics.

According to the present invention, there is provided an oxide semiconductor constituted by an oxide composite that has a pyrochlore structure containing Sn and Nb, wherein a composition ratio of Sn/Nb is 0.81≤Sn/Nb<1.0. In addition, the oxide semiconductor according to the present invention has an electron hole that serves as a charge carrier.

According to the present invention, it is possible to achieve a transparent semiconductor having a wide bandgap and high mobility in the oxide semiconductor. In addition, it is possible to achieve a p-type oxide semiconductor by the oxide semiconductor of the present invention. The oxide semiconductor of the present invention has a pyrochlore structure containing Sn and Nb such that a wide bandgap of 2.2 eV can be achieved, whereby the oxide semiconductor has high transparency in the visible spectrum.

In the oxide semiconductor according to the present invention, an upper edge of a valence band includes Sn-5s components. With this arrangement, since an s-orbital has an isotropic spherical shape with a large orbital radius, it is possible to achieve a significant effect in which localization of electrons is reduced and high mobility is obtained even with a turbulent structure.

The semiconductor according to the present invention is constituted by an oxide and has weather resistance, so that it is possible to achieve an electronic device having excellent weather resistance by forming the p-n junction with using the p-type oxide semiconductor of the present invention and an n-type oxide semiconductor.

### BRIEF DESCRIPTION OF THE DRAWINGS

FIG. 1 is a graph showing X-ray diffraction patterns when analytical composition ratios (Sn/Nb)_{after} of an oxide composite in a first embodiment are 0.68, 0.81, 0.91 and 0.998;

FIG. 2 is a graph showing a relationship between initial composition ratios (Sn/Nb)_{before} and the analytical composition ratios (Sn/Nb)_{after} after sintering in the first embodiment;

FIG. 3 is a graph showing changes in specific electrical resistances with respect to the analytical composition ratios (Sn/Nb)_{after} in the first embodiment; and

FIG. 4 is a graph showing changes in charge carrier concentration with respect to the analytical composition ratios (Sn/Nb)_{after} in the first embodiment.

### DETAILED DESCRIPTION

Hereinafter, an embodiment according to the present invention will be described.

The present inventors have focused on the fact that semiconductor properties are influenced by composition ratios of Sn/Nb, have conducted research and development on an oxide composite having a pyrochlore structure, and have obtained an oxide semiconductor having excellent semiconductor properties in addition to having p-type semiconductor properties.

The oxide semiconductor according to the embodiment of the present invention is a semiconductor in which Nb₂O₅ is bonded to SnO having a small bandgap and including an Sn-5s-orbital in an upper edge of a valence band, so that a multiple oxide is formed to enhance ion binding properties, and a crystal structure represented by a composition formula of Sn₂Nb₂O₇ in which a wide bandgap is achieved has the pyrochlore structure containing Sn and Nb whose composition ratio Sn/Nb is 0.81≤Sn/Nb<1.0.

In addition, the oxide semiconductor according to the embodiment of the present invention is a semiconductor represented by Sn₂Nb₂O₇ in which Sn has a composition ratio that is less than a stoichiometric composition ratio such that electron holes serving as p-type charge carriers are formed. This semiconductor further has a structural defect referred to as “V″_{Sn}” in a Kroger-Vink notation which is a notation for structural defects.

A mechanism in which p-type semiconductor properties are exhibited can be considered as described below.

As described above with reference to M. A. Subramanian, G. Aravamudan, G. V. Subba Rao, Progress in Solid State Chemistry 15, 55 (1983), the two structural defects in the compound represented by the simple composition formula of Sn₂Nb₂O₇ can be represented by Sn₂₋ₓ(Nb_{2-y}Sn_{y})O_{7-x-0.5y}. The pyrochlore structure is maintained in the range of x, y=0.1 to 0.48.

Regarding the two structural defects, these defects are respectively referred to as V″_{Sn} and Sn′_{Nb} according to the Kroger-Vink notation, meaning that both are structural defects having at least one negative charge. Therefore, when these defects are generated, both defects are considered to be structural defect centers that generate electron holes. In other words, Sn/Nb being less than the stoichiometric composition ratio, that is, Sn/Nb<1, indicates the structural defect referred to as V″_{Sn}. In Sn₂Nb₂O₇, SnO has a vapor pressure larger than that of Nb₂O₅, so that Sn is preferentially volatilized with respect to Nb in a sintering process during synthesis of a compound, which is considered to result in generation of V″_{Sn}.

None of the conventional oxide composites having the pyrochlore structure, including the oxide composite disclosed in the above-described M. A. Subramanian, G. Aravamudan, G. V. Subba Rao, Progress in Solid State Chemistry 15, 55 (1983), have achieved p-type semiconductor properties. A possible reason is that generation of the negative-divalent defect V″_{Sn} causes a positive-divalent oxygen vacancy V″_{O} to be simultaneously generated and results in undesirable charge compensation, so that it is difficult to exhibit p-type conductivity by generation of electron holes. It is considered that the generated amounts of V″_{Sn} and V″_{O} depend on the temperature and atmospheric gas conditions in which the oxide composite is produced. In the present invention, generation of V″_{Sn} is controlled by changing the composition ratio Sn/Nb during sample preparation, whereas V″_{O} is controlled based on the atmospheric gas conditions. Accordingly, it is considered that the charge compensation due to simultaneous generation of V″_{Sn} and V″_{O} is prevented, thereby exhibiting p-type semiconductor properties. P-type semiconductor properties are exhibited both in bulk form and in thin-film form.

Examples of n-type semiconductors suitable for forming a p-n junction with a p-type semiconductor of the present embodiment include In₂O₃, ZnO, SnO₂ and base materials of these compounds to which impurities are added, such as Sn-doped In₂O₃, Al-doped ZnO, Ga-doped ZnO, Sb-doped SnO₂ and F-doped SnO₂. ZnO is particularly preferable because of a feature in which ZnO can be used to fabricate insulators and semiconductors by its easiness in carrier concentration control, and is also preferable from viewpoints that ZnO facilitates etching during patterning, has no problem in scarcity of raw materials, and the like.

### First Embodiment

In the present embodiment, the oxide semiconductor constituted by the oxide composite having the pyrochlore structure that contains Sn and Nb will be described. In the oxide composite having the pyrochlore structure constituted by Sn, Nb and oxygen, properties corresponding to the composition ratio Sn/Nb have been studied. As described below, the composition ratio Sn/Nb within a range of 0.81≤Sn/Nb<1.0 represents the pyrochlore structure and exhibits p-type semiconductor properties in which electron holes serve as charge carriers.

### Production of Oxide Composite Having Pyrochlore Structure that Contains Sn and Nb

### Example 1

SnO powders (purity: 99.5%, produced by Kojundo Chemical Laboratory Co., Ltd.) and Nb₂O₅ (purity: 99.9%, produced by Kojundo Chemical Laboratory Co., Ltd.) were weighed and placed in an agate mortar and were wet-mixed while adding ethanol (special grade, produced by Wako Pure Chemical Industries, Ltd.) for approximately one hour. At this time, SnO and Nb₂O₅ were mixed with each other such that atomic ratios of Sn to Nb (Sn/Nb) were 0.95, 1.00, 1.10, 1.20, 1.30 and 1.40. These initial composition ratios are hereinafter referred to as “(Sn/Nb)_{before}”. Table 1 collectively shows initial weights of these samples. Note that a sample having (Sn/Nb)_{before} of 0.85 corresponds to Comparative Example 1 described below.

TABLE 1

| (Sn/Nb)_{before} | SnO | Nb₂O₅ |
|---|---|---|
| 0.85 | 2.301 g | 2.665 g |
| 0.95 | 2.572 g | 2.665 g |
| 1.00 | 2.707 g | 2.665 g |
| 1.10 | 2.707 g | 2.932 g |
| 1.20 | 2.707 g | 3.198 g |
| 1.30 | 2.707 g | 3.465 g |
| 1.40 | 2.707 g | 3.731 g |

Each mixture was then allowed to stand at room temperature overnight to dry the ethanol and was roughly divided into six mounds of powder which were then subjected to uniaxial compression (15 mm diameter, 170 MPa), whereby six disk-shaped compacts were prepared. Each compact was then placed on an alumina boat and was put in an electric furnace provided with an alumina tube having a diameter of 50 mm and a length of 800 mm. The compact was pre-sintered at 900° C. for 4 hours while flowing nitrogen gas at a flow rate of 150 ml/min. The pre-sintered compact was disintegrated in the agate mortar, and a polyvinyl alcohol aqueous solution serving as a binder was added to this sample such that the solution was 2 wt. % with respect to the sample. The sample was mixed together with ethanol and was allowed to stand overnight at room temperature to dry. The sample was then sieved to have particle sizes less than or equal to 212 μm, and the sieved particles were subjected to uniaxial compression (15 mm diameter, 170 MPa) and then to isostatic pressing (285 MPa), whereby a body having a diameter of approximately 15 mm and a thickness of approximately 1.2 mm was prepared. The obtained body was placed on an alumina boat and was sintered at 1100° C. for 4 hours while flowing nitrogen gas (flow rate: 150 ml/min). As shown in Table 2 described below, Samples No. 1 to No. 5 are samples respectively having initial composition ratios ((Sn/Nb_{before}) of 1.40, 1.30, 1.20, 1.00 and 0.95, and were prepared under a condition in which the flow rate of nitrogen gas (N₂ gas) at the time of sintering was 150 ml/min.

### Comparative Example 1

Comparative Example 1 is similar to Example 1, except that SnO and Nb₂O₅ were mixed such that the atomic ratio of Sn to Nb (Sn/Nb) was 0.85. Comparative Example 1 (Sample No. 6) was prepared under conditions similar to those of Example 1, and the flow rate of nitrogen gas (N₂ gas) at the time of sintering was 150 ml/min.

### Example 2

Example 2 was prepared under conditions similar to Example 1, except that the flow rate of nitrogen gas (N₂ gas) at the time of sintering was different from that of Example 1. As shown in Table 2 described below, Samples No. 7 to No. 12 are samples respectively having initial composition ratios ((Sn/Nb)_{before}) of 1.40, 1.30, 1.20, 1.10, 1.00 and 0.95, and were prepared under a condition in which the flow rate of nitrogen gas (N₂ gas) at the time of sintering was 50 ml/min.

### Example 3

Example 3 was prepared under conditions similar to Example 1, except that the flow rate of nitrogen gas (N₂ gas) at the time of sintering was different from that of Example 1. As shown in Table 2 described below, Samples No. 13 and No. 14 are samples respectively having initial composition ratios ((Sn/Nb)_{before}) of 1.30 and 1.00, and were prepared under a condition in which the flow rate of nitrogen gas (N₂ gas) at the time of sintering was 20 ml/min.

[Analytical Composition Ratio and Electrical Properties of Oxide Composite Having Pyrochlore Structure that Contains Sn and Nb]

Crystal structure identification of the samples obtained in Examples 1, 2, 3 and Comparative Example 1 were conducted by using an X-ray diffractometer (Panalital X'Pert Pro MRD). Estimates of the composition ratios of Sn/Nb after sintering were measured by using a wavelength dispersive X-ray fluorescence spectrometer (Rigaku ZSX). Analytical composition ratios after sintering are referred to as “(Sn/Nb)_{after}”. Each circular sample was prepared with gold electrodes vapor-deposited at four positions on edges of the sample, and evaluation of electrical properties of the samples were conducted by using a Hall effect measurement system (TOYO Corporation, Resitest 8310) based on a van der Pauw arrangement. All measurements were performed at room temperature.

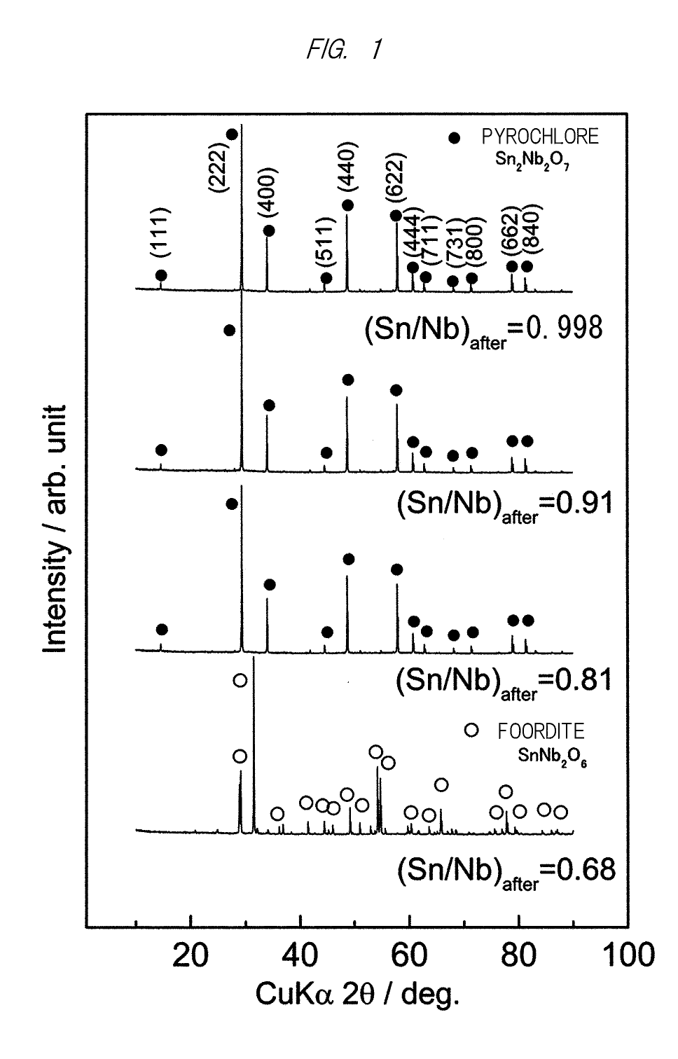

FIG. 1 shows changes in X-ray diffraction patterns corresponding to (Sn/Nb)_{after} of the Sn₂Nb₂O₇ samples. The horizontal axis of FIG. 1 corresponds to a diffraction angle 2Θ relative to an incident angle Θ measured by using a CuKα ray. When values of (Sn/Nb)_{after} are 0.81, 0.91 and 0.998, the X-ray diffraction patterns show significant peaks (indicated by closed circles (222), (400), (440), (622) and the like) attributed to Sn₂Nb₂O₇ having the pyrochlore structure that belongs to a cubic crystal system. On the other hand, when (Sn/Nb)_{after} is 0.68, the pattern shows a peak attributed to SnNb₂O₆O₆ having a foordite structure that belongs to a monoclinic system, indicating that no pyrochlore structure is obtained. Accordingly, it is understood that each sample having the analytical composition ratios within the range of 0.81≤(Sn/Nb)_{after}<1.00 is Sn₂Nb₂O₇ having the pyrochlore structure that belongs to the cubic crystal system.

Table 2 collectively shows the analytical composition ratios (Sn/Nb)_{after} and electrical measurement results (specific electrical resistance, charge carrier concentration, mobility, charge carrier type) corresponding to the samples prepared by changing the initial composition ratios ((Sn/Nb)_{before}) and the flow rates of nitrogen gas (N₂ gas) at the time of sintering.

TABLE 2

| | | Initial | | Measurement Results | | | | |
|---|---|---|---|---|---|---|---|---|
| | | Conditions | | | Specific | | | |
| | | | N₂ Flow | | Electrical | Charge Carrier | | Charge |
| | Sample | (Sn/Nb) | Rate | (Sn/Nb) | Resistance | Concentration | Mobility | Carrier |
| | No. | before | (ml/min) | after | (×10² Ωcm) | (×10¹⁵ cm⁻³) | (×10⁻² cm²V⁻¹s⁻¹) | Type |
| Example 1 | 1 | 1.40 | 150 | 0.980 | 20.0 | 13.1 | 29.0 | P |
| | 2 | 1.30 | 150 | 0.969 | 17.5 | 35.7 | 11.9 | P |
| | 3 | 1.20 | 150 | 0.887 | 84.6 | 47.5 | 18.8 | P |
| | 4 | 1.00 | 150 | 0.838 | 15.0 | 74.4 | 134 | P |
| | 5 | 0.95 | 150 | 0.811 | 9.88 | 4630 | 2.34 | P |
| Comparative | 6 | 0.85 | 150 | 0.675 | — | — | — | — |
| Example 1 | | | | | | | | |
| Example 2 | 7 | 1.40 | 50 | 0.940 | 51.1 | 2.30 | 59.2 | P |
| | 8 | 1.30 | 50 | 0.998 | 36.3 | 8.88 | 20.2 | P |
| | 9 | 1.20 | 50 | 0.907 | 20.3 | 81.7 | 4.63 | P |
| | 10 | 1.10 | 50 | 0.869 | 8.71 | 197 | 6.06 | P |
| | 11 | 1.00 | 50 | 0.853 | 2.27 | 2450 | 1.16 | P |
| | 12 | 0.95 | 50 | 0.821 | 1.38 | 5120 | 1.32 | P |
| Example 3 | 13 | 1.30 | 20 | 0.975 | 15.9 | 7.31 | 64.0 | P |
| | 14 | 1.00 | 20 | 0.862 | 4.01 | 945 | 2.26 | P |

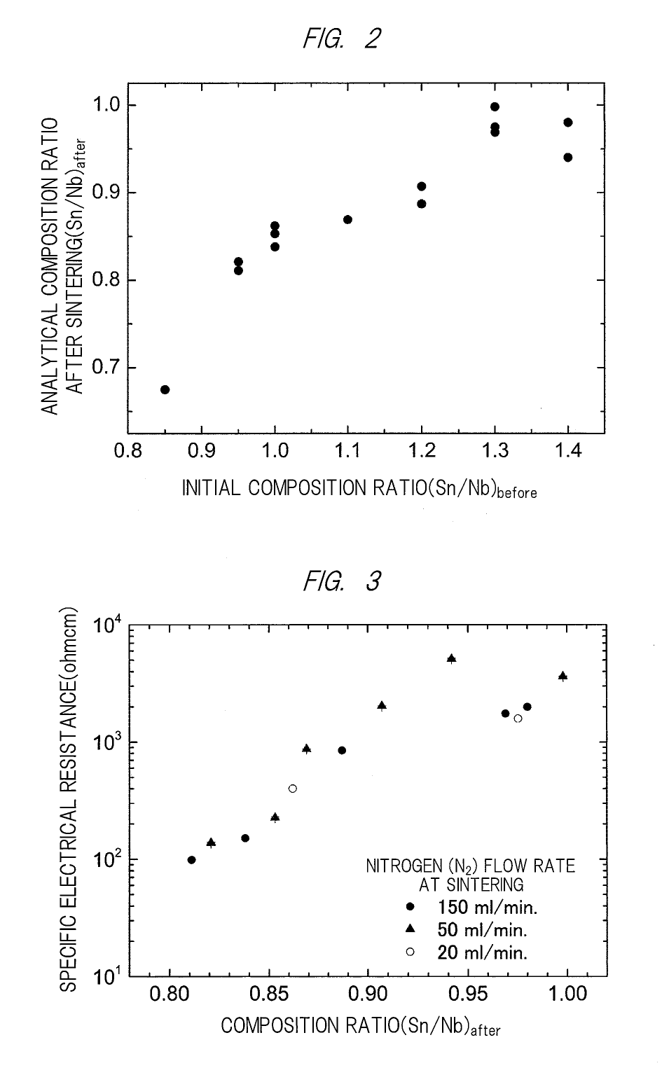

FIG. 2 shows plotted values of the initial composition ratios ((Sn/Nb)_{before}) and the analytical composition ratios ((Sn/Nb)_{after}) of the samples after sintering. When the initial composition ratios are within a range of 0.85≤(Sn/Nb)_{before}≤1.3, (Sn/Nb)_{after} increases as (Sn/Nb)_{before} increases. However, the value of (Sn/Nb)_{after} decreases when (Sn/Nb)_{before}=1.4. It is considered that this is because excessive Sn that is not included in the pyrochlore structure preferentially evaporates at the time of sintering. In other words, the result shows that it is difficult for the compound represented by the composition formula of Sn₂Nb₂O₇ having the pyrochlore structure to obtain the analytical composition ratio (Sn/Nb)_{after} of 1.0≤(Sn/Nb)_{after} after sintering. Therefore, in the present embodiment, the composition ratio that is specifically less than the stoichiometric composition ratio, that is, the composition ratio of Sn/Nb<1, is obtained.

FIG. 3 shows changes in specific electrical resistances with respect to (Sn/Nb)_{after}. FIG. 3 shows the specific electrical resistances when (Sn/Nb)_{after} are within a range of approximately 0.81 to approximately 1.0. It can be seen that the specific electrical resistances of the samples decrease as (Sn/Nb)_{after} decreases, indicating that there is a good correlation between the specific electrical resistances and (Sn/Nb)_{after}. FIG. 3 shows cases where nitrogen flow rates at the time of sintering are 150 ml/min. (closed circle), 50 ml/min. (closed triangle) and 20 ml/min. (open circle). Note that error bars in the drawing indicate standard deviation σ.

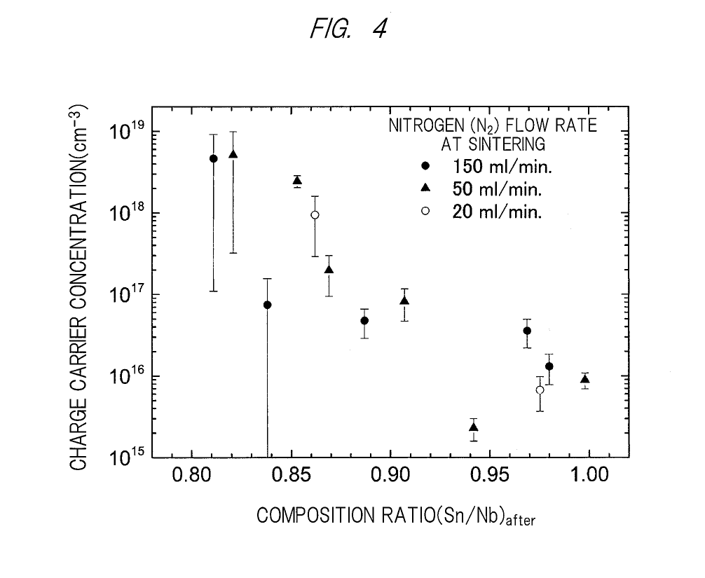

FIG. 4 shows changes in charge carrier concentration with respect to (Sn/Nb)_{after}. FIG. 4 also shows cases where nitrogen flow rates at the time of sintering are 150 ml/min. (closed circle), 50 ml/min. (closed triangle) and 20 ml/min. (open circle). Error bars in FIG. 4 also indicate standard deviation σ. In FIG. 4, it can be seen that there is a large variation among the samples when (Sn/Nb)_{after} is within the range of approximately 0.81 to approximately 1.0, and the variation is larger than the result of the specific electrical resistances of FIG. 3, but the charge carrier concentration increases as (Sn/Nb)_{after} decreases. It is considered that a portion of Sn in the pyrochlore structure is vacant, and Sn/Nb decreasing causes a Sn-vacancy V″_{Sn} to be generated. Since the Sn-vacancy V″_{Sn} is a defect that generates a carrier electron hole, it is considered that the concentration of the electron hole serving as the charge carrier of the p-type semiconductor increases as V″_{Sn} increases.

It is clear from the results of the crystal phase identification by X-ray diffraction and the results of the evaluation of electrical properties by the Hall effect measurement described above that when the composition ratio Sn/Nb is 0.81≤Sn/Nb<1.0, the compound represented by the simple composition formula of Sn₂Nb₂O₇ shows a single-phase pyrochlore structure and exhibits p-type semiconductor properties in which electron holes serve as charge carriers.

A bulk composite produced by the foregoing method of producing an oxide composite has been described by way of example only, and similar p-type properties can be obtained in a thin-film composite. A thin-film oxide semiconductor can be obtained by manufacturing techniques of an oxide thin-film, such as spin coating and spray coating methods that use a solution as a starting material, and vacuum film formation techniques that include a sputtering method, a vapor deposition method by heating or by an electron beam, and an ion plating method.

Note that the examples given in the foregoing embodiment and the like are described in order to easily understand the present invention, and that the present invention is not to be limited to this embodiment and the like.

The oxide semiconductor of the present invention is capable of achieving p-type semiconductor properties, so that a p-n junction can be formed by n-type and p-type semiconductors that are transparent in the visible spectrum. The oxide semiconductor of the present invention is industrially useful in that it can be widely utilized for devices such as transmissive displays and transparent transistors.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. An oxide semiconductor comprising an oxide composite that has a pyrochlore structure containing Sn and Nb, wherein a composition ratio of Sn/Nb is 0.81≤Sn/Nb<1.0.

2. The oxide semiconductor according to claim 1, wherein an electron hole serves as a charge carrier.
